(19) United States
(12) Patent Application Publication
(10) Pub. No.: US 2017/0042064 A1
(43) Pub. Date: Feb. 9, 2017

(54) THERMAL MODULE

(71) Applicant: ASIA VITAL COMPONENTS CO., LTD., New Taipei City (TW)

(72) Inventors: Chih-Peng Chen, New Taipei City (TW); Huang-Pin Shen, New Taipei City (TW)

(21) Appl. No.: 14/820,562

(22) Filed: Aug. 7, 2015

(51) Int. Cl. H05K 7/20; F28D 15/02

(52) U.S. Cl. CPC H05K 7/20336; H05K 7/20409; F28D 15/0275

(57) ABSTRACT

A thermal module includes a heat pipe and a heat dissipation unit. The heat pipe has a main body and at least one first heat conduction section integrally radially and axially extending from a circumference of the main body. The heat dissipation unit has multiple radiating fins. The radiating fins are arranged at intervals. Each radiating fin is formed with a perforation. At least one first locating slit outward extend from the perforation. The main body and the first heat conduction section are respectively correspondingly fitted through the perforations and the first locating slits to tightly connect the heat pipe with the heat dissipation unit. The first heat conduction section of the heat pipe provides much larger heat conduction area for the heat pipe so that the heat conduction effect of the heat dissipation unit is greatly enhanced and the heat dissipation performance and efficiency are enhanced.

### BACKGROUND OF THE INVENTION

1. Field of the Invention

The present invention relates generally to a thermal module, and more particularly to a thermal module, which has greatly enhanced heat conduction effect and higher heat dissipation efficiency.

2. Description of the Related Art

With the advance of techniques, the number of transistors of an electronic component per unit area has become more and more. This leads to increase of heat generated by the transistors in working. On the other hand, the working frequency of the electronic component has become higher and higher. In working, the transistors are switched on/off to generate heat. This also causes increase of the heat generated by the electronic component. The heat needs to be properly dissipated in time. Otherwise, the heat will cause deterioration of operation speed of the chip. In some more serious cases, the heat will even affect the lifetime of the chip. In order to enhance the heat dissipation effect of the electronic component, the heat is transferred to the radiating fins of a heat sink to dissipate the heat to the environment by way of natural convection or forced convection.

A heat pipe is able to transfer a great amount of heat to a remote place for dissipating the heat under a condition of very small cross-sectional area and temperature difference without any additional power supply. In consideration of the economical advantages of power-free and space utility, various heat pipes have been widely applied to electronic products as the most important heat transfer components.

The most often employed heat dissipation means is a heat dissipation device (such as a heat sink) mounted on a heat generation component, especially a heat sink equipped with a heat pipe structure. The heat sink is made of a high-heat-conductivity material. A working fluid and a capillary structure are disposed in the heat pipe to transfer heat. Therefore, the heat sink has high heat conduction performance and the heat sink has the advantage of lightweight structure. This can minimize the increase of weight of the electronic product due to the heat dissipation device, lower the cost and simplify the system.

The conventional heat pipe heat sink structure includes multiple radiating fins and at least one heat pipe. Each radiating fin has at least one perforation. The heat pipe is fitted through the perforations to assemble the heat pipe with the radiating fins. The conventional heat pipe has a simple circular or elliptic cross section. Therefore, the heat pipe contacts the radiating fins by a very small area (point-to-point contact). Accordingly, when the heat is transferred from the heat pipe to the radiating fins, the heat transfer range and speed are limited. As a result, the heat conduction effect is poor and the heat dissipation rate is lower.

In conclusion, the conventional heat sink has the following shortcomings:
1. The heat conduction effect is poor.
   2. The heat dissipation rate is lower.

### SUMMARY OF THE INVENTION

It is therefore a primary object of the present invention to provide a thermal module, which has greatly enhanced heat conduction effect and better heat dissipation performance.

It is a further object of the present invention to provide the above thermal module, which has a higher heat dissipation rate.

To achieve the above and other objects, the thermal module of the present invention includes a heat pipe and a heat dissipation unit. The heat pipe has a main body and at least one first heat conduction section integrally outward radially and axially extending from a circumference of the main body in a continuous or discontinuous state. The heat dissipation unit has multiple radiating fins. The radiating fins are arranged at intervals. Each radiating fin is formed with a perforation. At least one first locating slit outward extend from the perforation. The main body and the first heat conduction section are respectively correspondingly fitted through the perforations and the first locating slits to tightly connect the heat pipe with the heat dissipation unit.

According to the above arrangement, the main body and the first heat conduction section are integrally formed. Therefore, when a heat source contacts the heat pipe to transfer the heat generated by the heat source through the main body and the first heat conduction section of the heat pipe to the heat dissipation unit, the heat will be transferred to the radiating fins through both the main body and the first heat conduction section. The first heat conduction section outward extends from the main body so that the heat will be transferred from the main body to the first heat conduction section and then transferred from the first heat conduction section to every part of the radiating fins to dissipate the heat. The first heat conduction section is a heat dissipation face with a large area so that the contact area between the first heat conduction section and the radiating fins is larger to increase the heat conduction area. In this case, the heat conduction effect is greatly enhanced and the heat dissipation efficiency is greatly enhanced.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the thermal module of the present invention;

FIG. 2 is a perspective assembled view of the first embodiment of the thermal module of the present invention;

FIG. 3 is a front view of the first embodiment of the thermal module of the present invention;

FIG. 4 is a perspective exploded view of a second embodiment of the thermal module of the present invention;

FIG. 5 is a front view of the second embodiment of the thermal module of the present invention;

FIG. 6 is a perspective exploded view of a third embodiment of the thermal module of the present invention;

FIG. 7 is a perspective exploded view of a fourth embodiment of the thermal module of the present invention;

FIG. 8 is a perspective exploded view of a fifth embodiment of the thermal module of the present invention;

FIG. 9 is a perspective assembled view of the fifth embodiment of the thermal module of the present invention; and

FIG. 10 is a perspective exploded view of a sixth embodiment of the thermal module of the present invention.

### DETAILED DESCRIPTION OF THE PREFERRED EMBODIMENTS

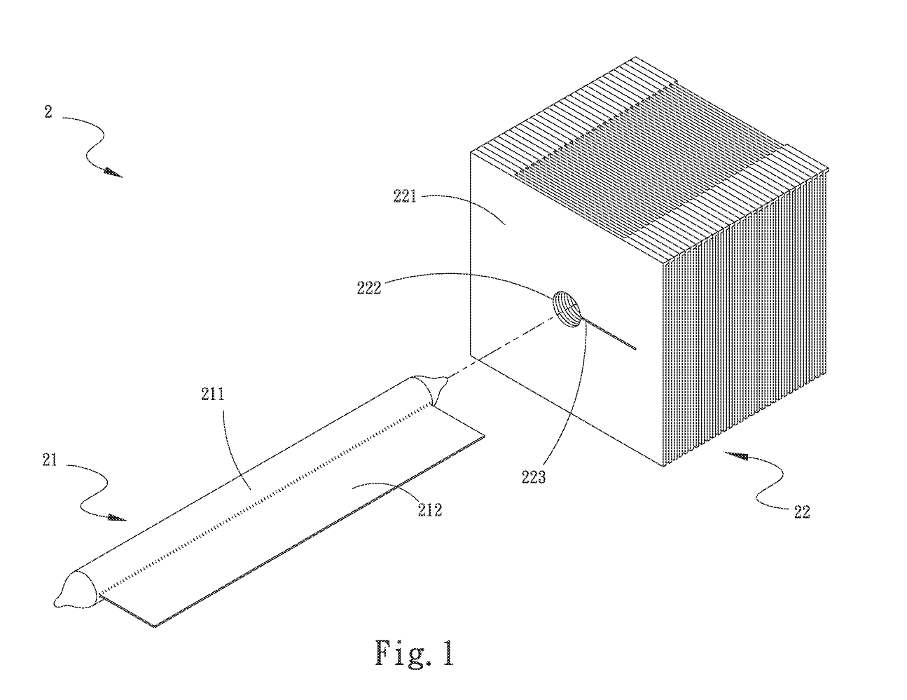

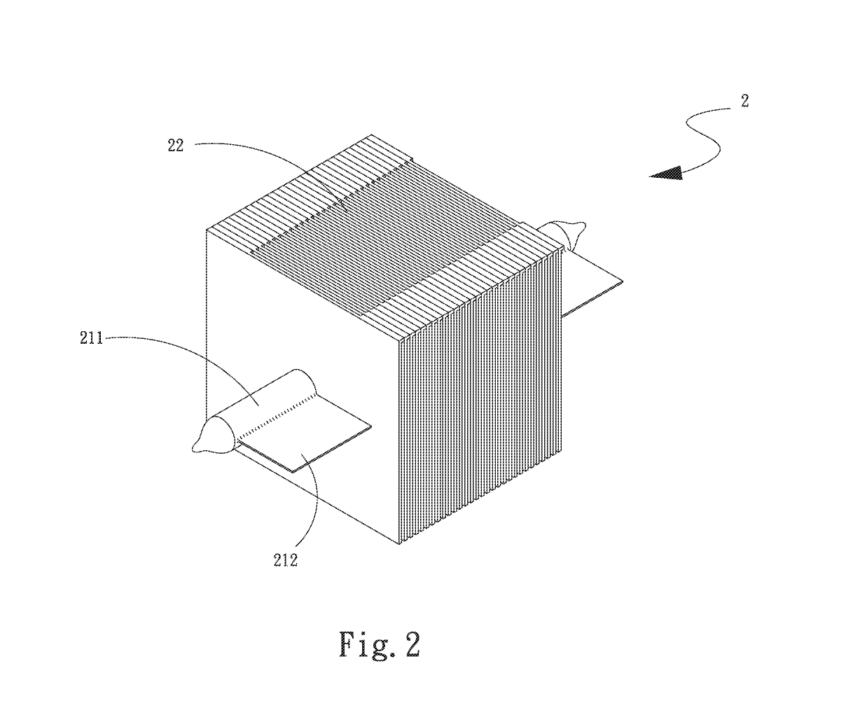

Please refer to FIGS. 1 and 2. FIG. 1 is a perspective exploded view of a first embodiment of the thermal module of the present invention. FIG. 2 is a perspective assembled view of the first embodiment of the thermal module of the present invention. As show in the drawings, the thermal module 2 of the present invention includes a heat pipe 21 and a heat dissipation unit 22. The heat pipe 21 has a main body 211 and at least one first heat conduction section 212 continuously or discontinuously integrally radially extending from a circumference of the main body 211. The first heat conduction section 212 also extends in an axial direction of the main body 211. The heat dissipation unit 22 is composed of multiple radiating fins 221 stacked on each other and arranged at intervals. Each radiating fin 221 is formed with a perforation 222. At least one first locating slit 223 outward extends from the perforation 222. The main body 211 and the first heat conduction section 212 are respectively correspondingly fitted through the perforations 222 and the first locating slits 223 to connect the heat pipe 21 with the heat dissipation unit 22.

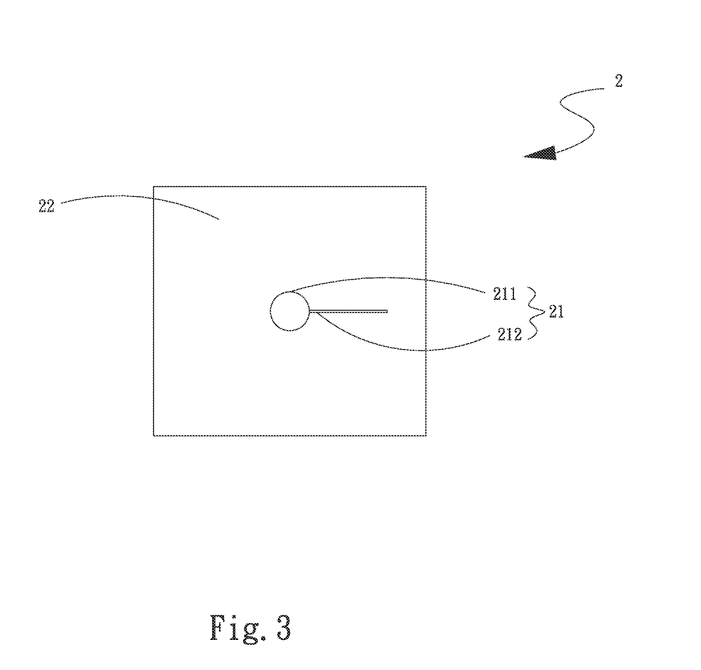

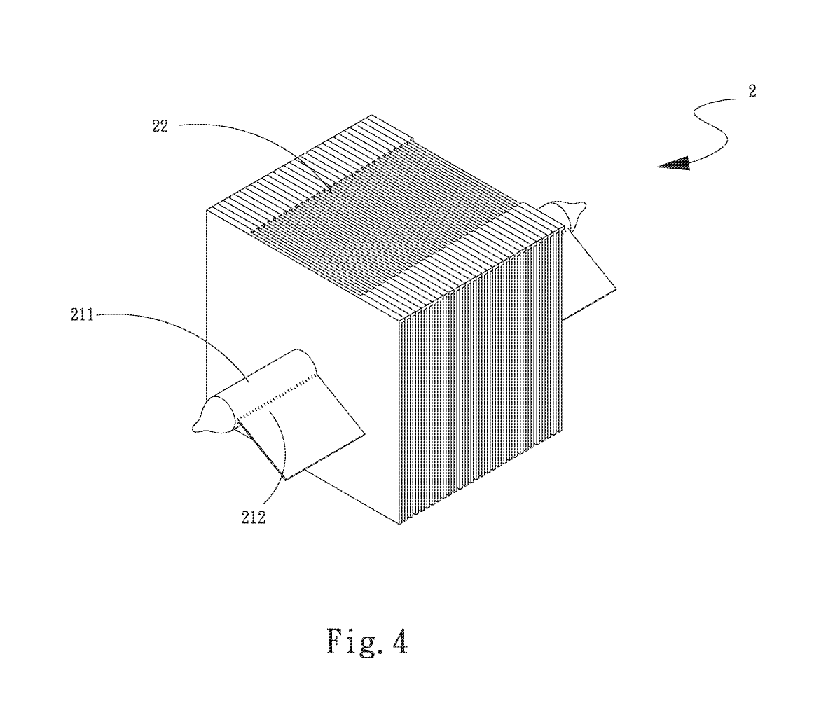

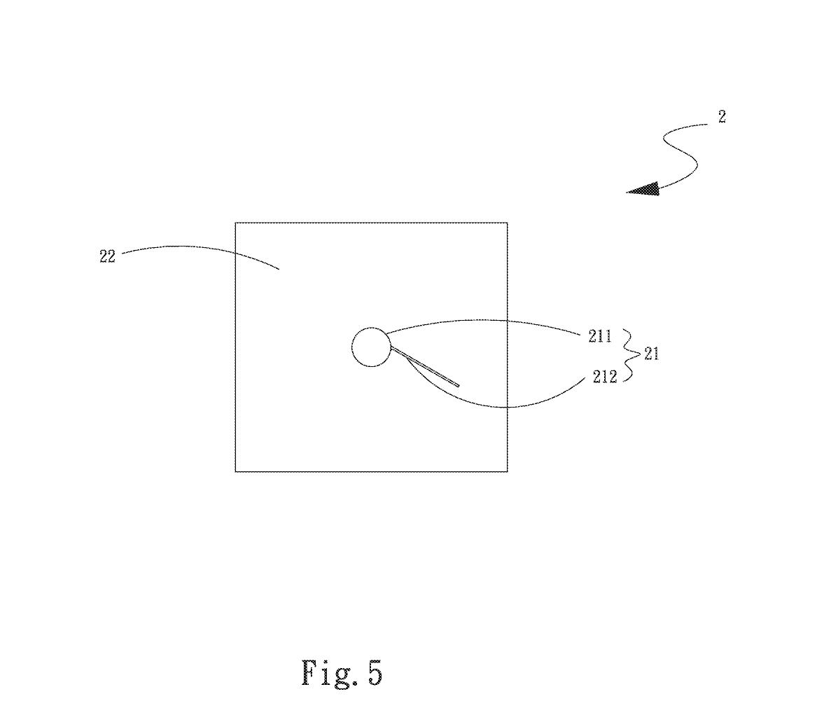

Please now refer to FIG. 3. FIG. 3 is a front view of the first embodiment of the thermal module of the present invention. In this embodiment, the first heat conduction section 212 is normal to the main body 211. Also, the corresponding first locating slit 223 is normal to the perforation 222 (as shown in FIG. 3). Alternatively, the first heat conduction section 212 can be inclined from the main body 211 by any angle (as in the second embodiment shown by FIGS. 4 and 5). In the second embodiment, the heat pipe 21 is also correspondingly fitted through the heat dissipation unit 22. In addition, in this embodiment, the heat pipe has a circular cross section.

According to the above arrangement, the main body 211 and the first heat conduction section 212 are integrally formed and the first heat conduction section 212 provides a larger heat conduction area for the heat pipe. Therefore, when a heat source (not shown) contacts the heat pipe 21 to transfer the heat generated by the heat source through the main body 211 and the first heat conduction section 212 of the heat pipe 21 to the radiating fins 221, the heat will be transferred to the heat dissipation unit 22 through both the main body 211 and the first heat conduction section 212. The first heat conduction section 212 contacts the radiating fins 221 by large area so that the heat conduction area is increased to quickly transfer the heat to the heat dissipation unit 22 for dissipating the heat. Accordingly, the heat dissipation efficiency is greatly enhanced.

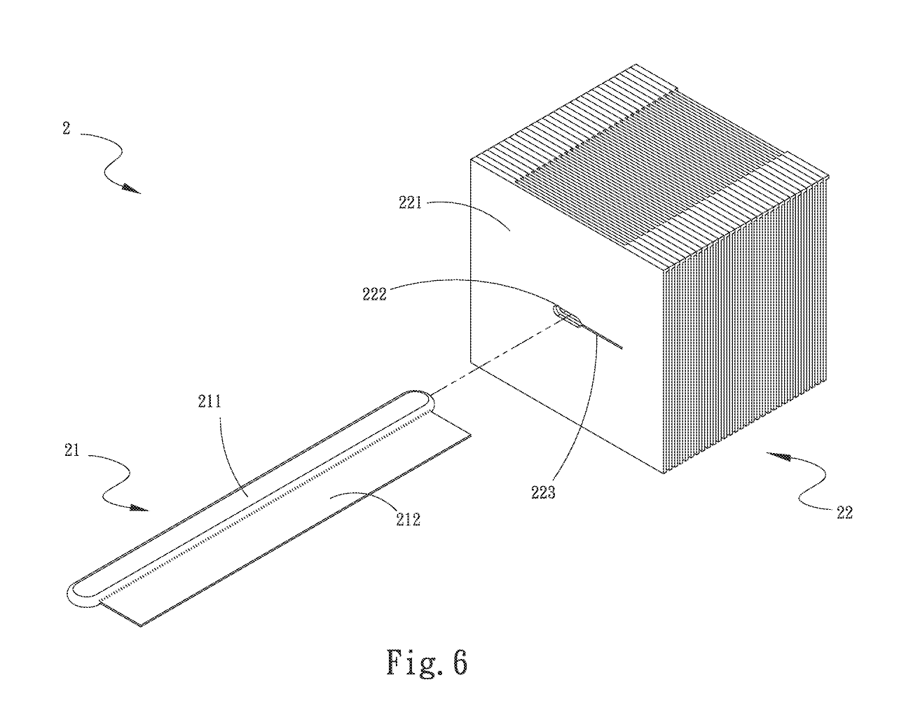

Please now refer to FIG. 6, which is a perspective exploded view of a third embodiment of the thermal module of the present invention. The third embodiment is partially identical to the first embodiment in component and relationship between the components and thus will not be repeatedly described hereinafter. The third embodiment is mainly different from the first embodiment in that in the third embodiment, the heat pipe 21 is, but not limited to, a flat heat pipe. In practice, the heat pipe 21 can have an elliptic cross section or a cross section with any other shape according to the requirement of a user. This can achieve the same effect.

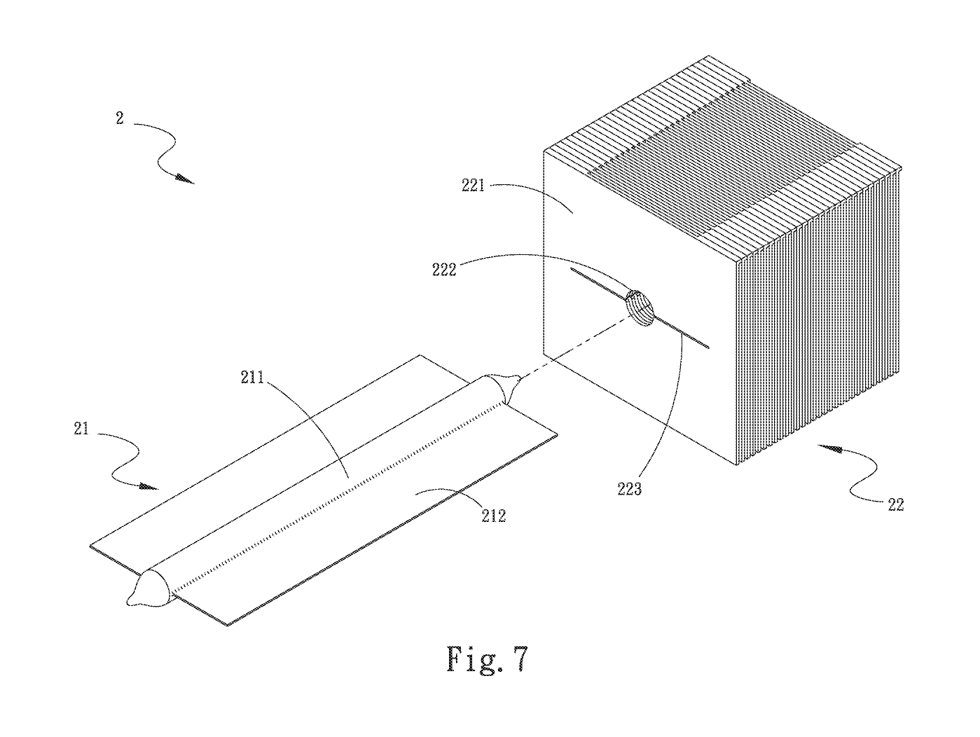

Please now refer to FIG. 7, which is a perspective exploded view of a fourth embodiment of the thermal module of the present invention. The fourth embodiment is partially identical to the first embodiment in component and relationship between the components and thus will not be repeatedly described hereinafter. The fourth embodiment is mainly different from the first embodiment in that in the fourth embodiment, two first heat conduction sections 212 integrally outward extend from the circumference of the main body 211. Two first locating slits 223 outward extend from the perforation 222 of the radiating fin 221 corresponding to the first heat conduction sections 212. The two first heat conduction sections 212 are correspondingly fitted through the two first locating slits 223 to connect the heat pipe 21 with the heat dissipation unit 22. In this embodiment, the number of the first heat conduction sections 212 is two for illustration purposes. In practice, the number of the first heat conduction sections 212 can be freely increased according to the requirement of a user. This can achieve the same effect.

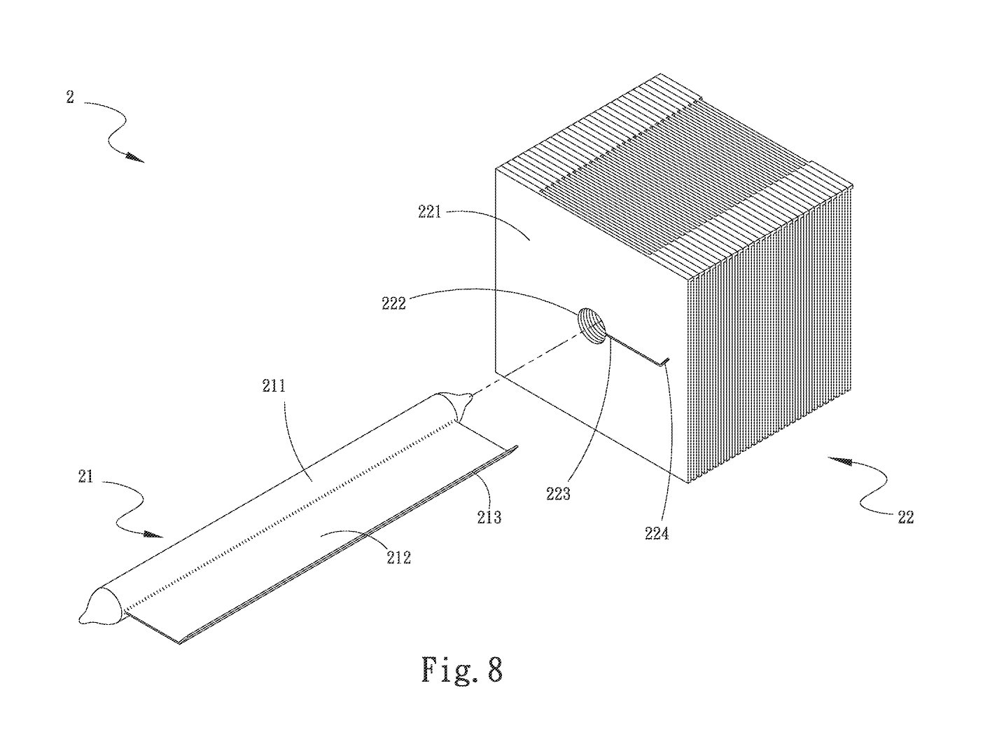

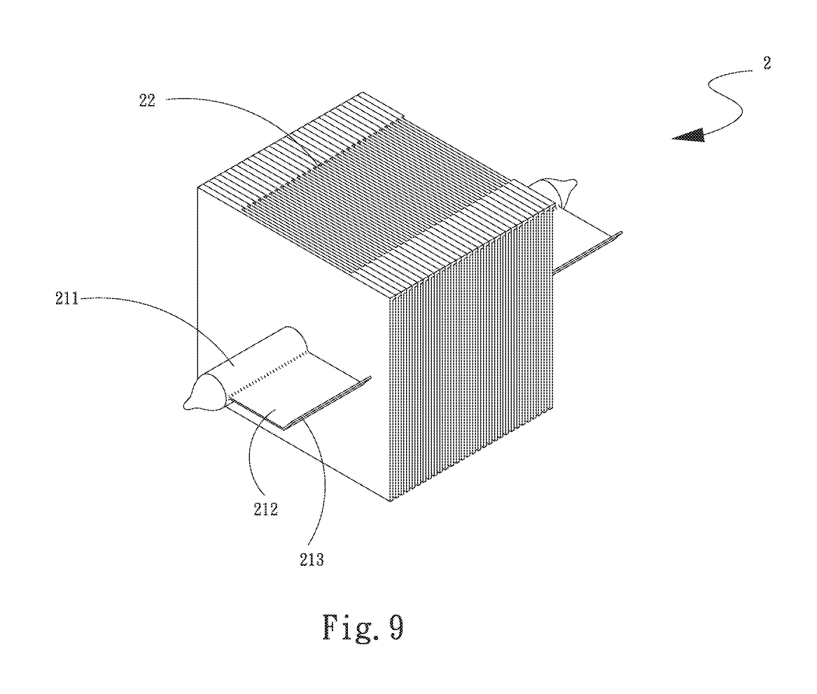

Please now refer to FIGS. 8 and 9. FIG. 8 is a perspective exploded view of a fifth embodiment of the thermal module of the present invention. FIG. 9 is a perspective assembled view of the fifth embodiment of the thermal module of the present invention. The fifth embodiment is partially identical to the first embodiment in component and relationship between the components and thus will not be repeatedly described hereinafter. The fifth embodiment is mainly different from the first embodiment in that in the fifth embodiment, the first heat conduction section 212 further has a second heat conduction section 213. The second heat conduction section 213 integrally extends from the first heat conduction section 212. The first heat conduction section 212 and the second heat conduction section 213 contain an angle ranging from 0 degree to 360 degrees. A second locating slit 224 further outward extends from the first locating slit 223. The second heat conduction section 213 is correspondingly fitted through the second locating slit 224.

According to the above arrangement, the first and second heat conduction sections 212, 213 outward extend from the main body 211. After the heat is transferred from the main body 211 to the first and second heat conduction sections 212, 213, the heat will be quickly further transferred from the first and second heat conduction sections 212, 213 to every part of the radiating fins 221 to dissipate the heat. Therefore, the heat conduction area is increased to greatly enhance the heat dissipation effect.

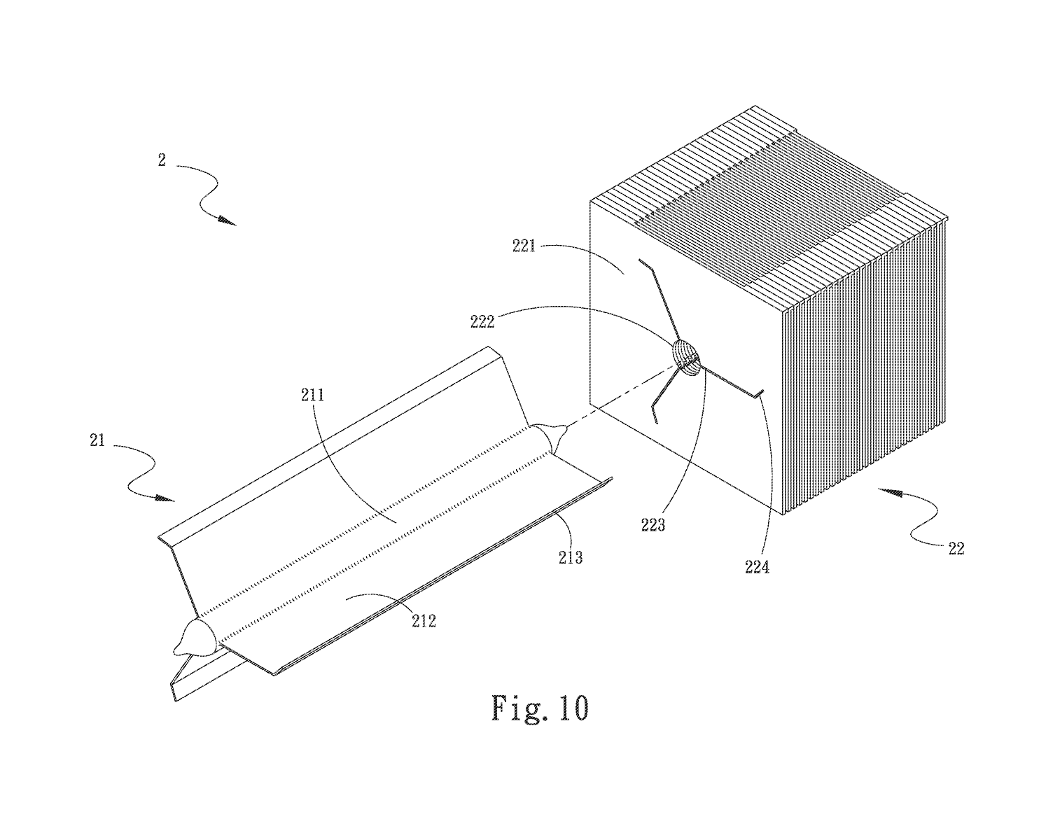

Finally, please refer to FIG. 10, which is a perspective exploded view of a sixth embodiment of the thermal module of the present invention. The sixth embodiment is partially identical to the first embodiment in component and relationship between the components and thus will not be repeatedly described hereinafter. The sixth embodiment is mainly different from the first embodiment in that in the sixth embodiment, three first heat conduction sections 212 integrally outward extend from the circumference of the main body 211 and each first heat conduction section 212 has a second heat conduction section 213 further integrally outward extending from the first heat conduction section 212. Three first locating slits 223 outward extend from the perforation 222 of the radiating fin 221 corresponding to the three first heat conduction sections 212. Each first locating slit 223 has a second locating slit 224 further outward extending from the first locating slit 223. The main body 211 and the first and second heat conduction sections 212, 213 are respectively correspondingly fitted through the perforations 222 and the first and second locating slits 223, 224 to connect the heat pipe 21 with the heat dissipation unit 22. In this embodiment, the number of the first heat conduction sections 212 is three and the number of the second heat conduction sections 213 is also three for illustration purposes. In practice, the number of the first heat conduction sections 212 and the number of the second heat conduction sections 213 can be freely increased according to the requirement of a user. This can achieve the same effect.

In conclusion, in comparison with the conventional device, the present invention has the following advantages:
1. The first and second heat conduction sections contact the radiating fins by large area so that the heat conduction effect is enhanced.
2. The heat is dissipated more quickly.
3. The heat dissipation efficiency is greatly enhanced.

The present invention has been described with the above embodiments thereof and it is understood that many changes and modifications in the above embodiments can be carried out without departing from the scope and the spirit of the invention that is intended to be limited only by the appended claims.

What is claimed is:

1. A thermal module comprising:
a heat pipe having a main body and at least one first heat conduction section integrally radially extending from a circumference of the main body, the first heat conduction section also extending in an axial direction of the main body; and
a heat dissipation unit having multiple radiating fins, the radiating fins being arranged at intervals, each radiating fin being formed with a perforation, at least one first locating slit outward extending from the perforation, the main body and the first heat conduction section being respectively correspondingly fitted through the perforations and the first locating slits to connect the heat pipe with the heat dissipation unit.

2. The thermal module as claimed in claim 1, wherein the first heat conduction section further has a second heat conduction section, the second heat conduction section integrally extending from the first heat conduction section.

3. The thermal module as claimed in claim 2, wherein a second locating slit further outward extends from the first locating slit, the second heat conduction section being correspondingly fitted through the second locating slit.

4. The thermal module as claimed in claim 2, wherein the first heat conduction section and the second heat conduction section contain an angle ranging from 0 degree to 360 degrees.

5. The thermal module as claimed in claim 1, wherein the first heat conduction section continuously or discontinuously integrally radially extends from the circumference of the main body.
